(19) United States
(12) Patent Application Publication
(10) Pub. No.: US 2021/0305066 A1
(43) Pub. Date: Sep. 30, 2021

(54) SUBSTRATE PROCESSING METHOD AND SUBSTRATE PROCESSING APPARATUS

(71) Applicant: Tokyo Electron Limited, Tokyo (JP)

(72) Inventors: Song yun Kang, Tokyo (JP); Toshitake Tsuda, Tokyo (JP); Kenji Sekiguchi, Nirasaki City (JP); Syuhei Yonezawa, Nirasaki City (JP); Koji Kagawa, Koshi City (JP)

(21) Appl. No.: 17/212,225

(22) Filed: Mar. 25, 2021

(30) Foreign Application Priority Data
Mar. 26, 2020 (JP) 2020-055375

(51) Int. Cl. H01L 21/67; H01L 21/02; H01L 21/306; H01L 21/311

(52) U.S. Cl. CPC H01L 21/6708; H01L 21/67051; H01L 21/02129; H01L 21/31144; H01L 21/30604; H01L 21/02087; H01L 21/02343

(57) ABSTRACT

A substrate processing method includes holding a substrate on which a boron-containing silicon film is formed; supplying an oxidative aqueous solution including hydrofluoric acid and nitric acid to the held substrate; and etching the boron-containing silicon film of the substrate with the oxidative aqueous solution.

### CROSS-REFERENCE TO RELATED APPLICATION

This application claims the benefit of Japanese Patent Application No. 2020-055375 filed on Mar. 26, 2020, the entire disclosure of which is incorporated herein by reference.

### TECHNICAL FIELD

The various aspects and embodiments described herein pertain generally to a substrate processing method and a substrate processing apparatus.

### BACKGROUND

Conventionally, there is known a technique of using a carbon film or a boron film as a hard mask for use in etching a substrate such as a semiconductor wafer (hereinafter, sometimes referred to as “wafer”) (see, for example, Patent Document 1).
Patent Document 1: Japanese Patent Laid-open Publication No. 2018-164067

### SUMMARY

In one exemplary embodiment, a substrate processing method includes holding a substrate on which a boron-containing silicon film is formed; supplying an oxidative aqueous solution including hydrofluoric acid and nitric acid to the held substrate; and etching the boron-containing silicon film of the substrate with the oxidative aqueous solution.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is schematic plan view of a substrate processing system according to an exemplary embodiment;

FIG. 2 is a schematic side view of the substrate processing system according to the exemplary embodiment;

FIG. 3 is a schematic diagram of a periphery processing unit according to the exemplary embodiment;

FIG. 4 is a schematic diagram of a rear surface processing unit according to the exemplary embodiment;

FIG. 5 is a diagram showing a relationship between a ratio of hydrofluoric acid in an oxidative aqueous solution and an etching rate of a boron-containing silicon film;

FIG. 6 is a diagram showing a relationship between a temperature of the oxidative aqueous solution and an etching rate of the boron-containing silicon film;

FIG. 7 is a diagram showing a relationship between a boron concentration in the boron-containing silicon film and an etching rate of the boron-containing silicon film;

FIG. 8 is a diagram for describing a holding processing of holding a wafer in the periphery processing unit according to the exemplary embodiment;

FIG. 9 is a diagram for describing a supplying processing of supplying the oxidative aqueous solution to a peripheral portion of the wafer according to the exemplary embodiment;

FIG. 10 a diagram for describing a holding processing of holding the wafer in the rear surface processing unit according to the exemplary embodiment;

FIG. 11 is a diagram for describing a supplying processing of supplying the oxidative aqueous solution onto a rear surface of the wafer according to the exemplary embodiment;

FIG. 12 is a schematic plan view of a substrate processing system according to a modification example of the exemplary embodiment;

FIG. 13 is a schematic diagram illustrating a processing tub of an entire surface processing unit according to the modification example of the exemplary embodiment;

FIG. 14 is a flowchart illustrating a sequence of a substrate processing performed by the substrate processing system according to the exemplary embodiment; and

FIG. 15 is a flowchart illustrating a sequence of a substrate processing performed by the substrate processing system according to the modification example of the exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments of a substrate processing method and a substrate processing apparatus of the present disclosure will be described in detail with reference to the accompanying drawings. The present disclosure is not limited to the exemplary embodiments to be described below. Further, it should be noted that the drawings are schematic and relations in sizes of individual components and ratios of the individual components may sometimes be different from actual values. Even between the drawings, there may exist parts having different dimensional relationships or different ratios.

Conventionally, there is known a technique of using a carbon film or a boron film as a hard mask for use in etching a substrate such as a semiconductor wafer (hereinafter, sometimes referred to as “wafer”).

Recently, a boron-containing silicon film is attracting attention as a new hard mask material. However, a technique capable of appropriately etching the boron-containing silicon film formed on the wafer is yet to be found.

In this regard, there is still a demand for a technique capable of appropriately etching the boron-containing silicon film formed on the wafer.

<Outline of Substrate Processing System>

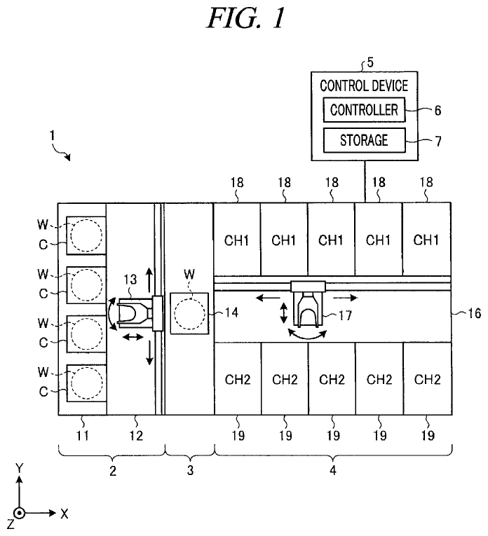

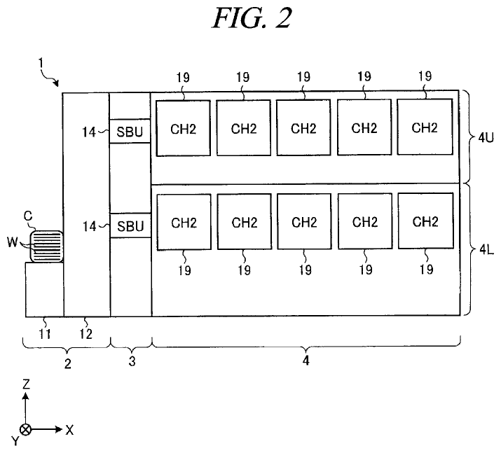

First, a schematic configuration of a substrate processing system 1 according to an exemplary embodiment will be described with reference to FIG. 1 and FIG. 2. FIG. 1 is a schematic plan view of the substrate processing system 1 according to the exemplary embodiment, and FIG. 2 is a schematic side view thereof.

Further, the substrate processing system 1 is an example of a substrate processing apparatus. In the following, in order to clarify positional relationships, the X-axis, Y-axis and Z-axis which are orthogonal to each other will be defined, and the positive Z-axis direction will be regarded as a vertically upward direction.

As depicted in FIG. 1, the substrate processing system 1 according to the exemplary embodiment is equipped with a carry-in/out station 2, a delivery station 3, and a processing station 4 which are arranged in this order.

In this substrate processing system 1, a substrate, i.e., a semiconductor wafer (hereinafter, referred to as “wafer W”) in the present exemplary embodiment carried from the carry-in/out station 2 is transferred into the processing station 4 via the delivery station 3, and processed in the processing station 4. Further, in the substrate processing system 1, the wafer W after being processed is returned back into the carry-in/out station 2 from the processing station 4 via the delivery station 3, and sent to an outside of the carry-in/out station 2.

The carry-in/out station 2 includes a cassette placing section 11 and a transfer section 12. A plurality of cassettes C each of which accommodates a multiple number of wafers W therein horizontally is provided in the cassette placing section 11.

The transfer section 12 is provided between the cassette placing section 11 and the delivery station 3, and has a first transfer device 13 inside. The first transfer device 13 is equipped with a plurality of (for example, five) wafer holders each of which is configured to hold a single sheet of wafer W.

The first transfer device 13 is configured to be movable horizontally and vertically and pivotable around a vertical axis and to transfer a plurality of wafers W between the cassette C and the delivery station 3 at the same time with the plurality of wafer holders.

Now, the delivery station 3 will be explained. As illustrated in FIG. 2, a multiplicity of substrate placing units (SBU) 14 are placed inside the delivery station 3. To elaborate, two substrate placing units 14 are respectively placed at a position corresponding to a first processing station 4U of the processing station 4 to be described below and a position corresponding to a second processing station 4L thereof.

The processing station 4 includes the first processing station 4U and the second processing station 4L. The first processing station 4U and the second processing station 4L are spatially separated from each other by a partition wall or a shutter, and are arranged in a height direction.

The first processing station 4U and the second processing station 4L have the same configuration. As shown in FIG. 1, each of the first and second processing stations 4U and 4L has a transfer section 16, a second transfer device 17, a plurality of periphery processing units (CH1) 18, and a plurality of rear surface processing units (CH2) 19.

The second transfer device 17 is disposed inside the transfer section 16, and transfers the wafer W between the substrate placing unit 14, the periphery processing unit 18 and the rear surface processing unit 19.

The second transfer device 17 is equipped with a single wafer holder configured to hold a single sheet of wafer W. The second transfer device 17 is configured to be movable horizontally and vertically and pivotable around a vertical axis and to transfer the single sheet of wafer W by using the wafer holder.

The plurality of periphery processing units 18 and the plurality of rear surface processing units 19 are arranged adjacent to the transfer section 16. As an example, the periphery processing units 18 are arranged at the positive Y-axis side of the transfer section 16 along the X-axis direction, whereas the rear surface processing units 19 are arranged at the negative Y-side of the transfer section 16 along the X-axis direction.

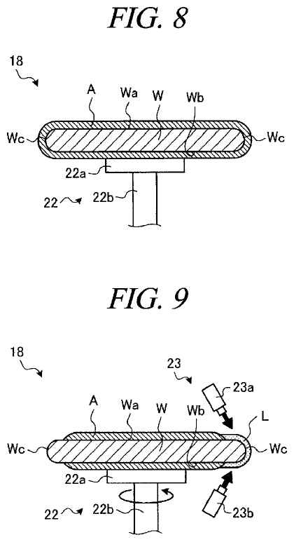

Each periphery processing unit 18 is configured to perform a preset processing on a peripheral portion Wc (see FIG. 8) of the wafer W. In the exemplary embodiment, the periphery processing unit 18 performs a processing of etching a boron-containing silicon film A (see FIG. 8) from the peripheral portion Wc of the wafer W.

Here, the peripheral portion Wc refers to an end surface of the wafer W and an inclined portion formed therearound. This inclined portion is formed at each of a front surface Wa (see FIG. 8) and a rear surface Wb (see FIG. 8) of the wafer W. Details of the periphery processing unit 18 will be elaborated later.

The boron-containing silicon film A formed on the wafer W is a film containing boron in a range from 20 atom % to 80 atom %. The rest of this film is made of silicon and an inevitable impurity. The boron-containing silicon film A is used as a hard mask when etching the wafer W, for example.

The inevitable impurity included in the boron-containing silicon film A may be hydrogen (H) originated from, for example, a film forming source material. For example, the boron-containing silicon film A contains the hydrogen in a range from 1 atom % to 20 atom %.

Each rear surface processing unit 19 is configured to perform a preset processing on the rear surface Wb of the wafer W. In the exemplary embodiment, the rear surface processing unit 19 performs a processing of etching the boron-containing silicon film A from the entire rear surface Wb of the wafer W. Details of the rear surface processing unit 19 will be elaborated later.

Further, as shown in FIG. 1, the substrate processing system 1 is equipped with a control device 5. The control device 5 is, for example, a computer, and includes a controller 6 and a storage 7. The storage 7 stores therein a program for controlling various kinds of processings performed in the substrate processing system 1. The controller 6 controls an operation of the substrate processing system 1 by reading and executing the program stored in the storage 7.

The program is recorded on a computer-readable recording medium and may be installed from this recording medium to the storage 7 of the control device 5. The computer-readable recording medium may be, by way of example, but not limitation, a hard disk (HD), a flexible disk (FD), a compact disk (CD), a magnet optical disk (MO), a memory card, or the like.

<Configuration of Periphery Processing Unit>

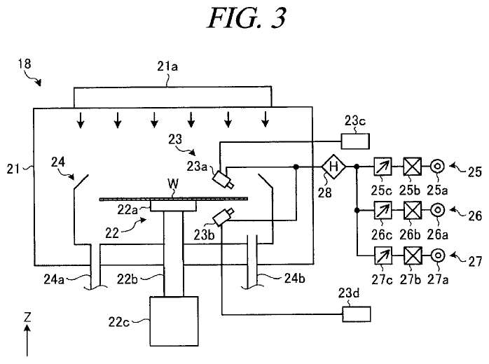

Now, a configuration of the periphery processing unit 18 according to the exemplary embodiment will be explained with reference to FIG. 3. FIG. 3 is a schematic diagram illustrating the periphery processing unit 18 according to the exemplary embodiment. As shown in FIG. 3, the periphery processing unit 18 is equipped with a chamber 21, a substrate holder 22, a processing liquid supply 23, and a recovery cup 24.

The chamber 21 accommodates therein the substrate holder 22, the processing liquid supply 23 and the recovery cup 24. A FFU (Fan Filter Unit) 21a configured to form a downflow within the chamber 21 is provided at a ceiling of the chamber 21.

The substrate holder 22 holds the wafer W rotatably. The substrate holder 22 includes a holder 22a configured to hold the wafer W horizontally; a supporting column member 22b vertically extending to support the holder 22a; and a driver 22c configured to rotate the supporting column member 22b around a vertical axis.

The holder 22a is connected to an intake device (not shown) such as a vacuum pump, and attracts the rear surface Wb (see FIG. 8) of the wafer W by using a negative pressure generated by an air intake of the intake device, thus allowing the wafer W to be held horizontally. By way of non-limiting example, a porous chuck, an electrostatic chuck, or the like may be used as the holder 22a.

The holder 22a has an attraction region having a diameter smaller than that of the wafer W. Accordingly, a chemical liquid discharged from a lower nozzle 23b of the processing liquid supply 23 to be described later can be supplied to the rear surface Wb of the peripheral portion We (see FIG. 8) of the wafer W.

The processing liquid supply 23 is equipped with an upper nozzle 23a and the lower nozzle 23b. The upper nozzle 23a is disposed above the wafer W held by the substrate holder 22, and the lower nozzle 23b is disposed under this wafer W.

A hydrofluoric acid supply 25, a nitric acid supply 26, and a rinse liquid supply 27 are connected to each of the upper nozzle 23a and the lower nozzle 23b in parallel. Further, a heater 28 is provided between the upper and lower nozzles 23a and 23b; and the hydrofluoric acid supply 25, the nitric acid supply 26 and the rinse liquid supply 27.

The hydrofluoric acid supply 25 has a hydrofluoric acid source 25a, a valve 25b and a flow rate controller 25c in this sequence from an upstream side. The hydrofluoric acid source 25a is, for example, a tank which stores hydrofluoric acid (HF) therein. The flow rate controller 25c adjusts a flow rate of the hydrofluoric acid which is supplied to the upper and lower nozzles 23a and 23b from the hydrofluoric acid source 25a via the valve 25b.

The nitric acid supply 26 has a nitric acid source 26a, a valve 26b and a flow rate controller 26c in this sequence from an upstream side. The nitric acid source 26a is, for example, a tank which stores nitric acid (HNO₃) therein. The flow rate controller 26c adjusts a flow rate of the nitric acid which is supplied from the nitric acid source 26a to the upper and lower nozzles 23a and 23b via the valve 26b.

The rinse liquid supply 27 has a rinse liquid source 27a, a valve 27b and a flow rate controller 27c in sequence from an upstream side. The rinse liquid source 27a is, for example, a tank which stores therein a rinse liquid such as, but not limited to, DIW (deionized water). The flow rate controller 27c adjusts a flow rate of the rinse liquid which is supplied from the rinse liquid source 27a to the upper and lower nozzles 23a and 23b via the valve 27b.

The upper nozzle 23a discharges a chemical liquid supplied from at least one of the hydrofluoric acid supply 25, the nitric acid supply 26 or the rinse liquid supply 27 onto the front surface Wa (see FIG. 8) of the peripheral portion Wc of the wafer W held by the substrate holder 22.

The lower nozzle 23b discharges the chemical liquid supplied from at least one of the hydrofluoric acid supply 25, the nitric acid supply 26 or the rinse liquid supply 27 onto the rear surface Wb (see FIG. 8) of the peripheral portion Wc of the wafer W held by the substrate holder 22.

Further, the periphery processing unit 18 is capable of heating the chemical liquid discharged from the upper and lower nozzles 23a and 23b to a predetermined temperature with the heater 28.

Further, the processing liquid supply 23 is equipped with a first moving device 23c configured to move the upper nozzle 23a and a second moving device 23d configured to move the lower nozzle 23b. By moving the upper and lower nozzles 23a and 23b by using the first and second moving devices 23c and 23d, a supply position of the chemical liquid onto the wafer W can be changed.

The recovery cup 24 is disposed to surround the substrate holder 22. A drain port 24a for draining the chemical liquid supplied from the processing liquid supply 23 to the outside of the chamber 21; and an exhaust port 24b for exhausting an atmosphere within the chamber 21 are formed at a bottom of the recovery cup 24.

The periphery processing unit 18 having the above-described configuration attracts and holds the rear surface Wb of the wafer W with the holder 22a, and then rotates the wafer W by using the driver 22c.

Subsequently, the periphery processing unit 18 discharges an oxidative aqueous solution L (see FIG. 9) from the upper nozzle 23a toward the front surface Wa of the peripheral portion Wc of the wafer W being rotated. Further, along with this discharging processing, the periphery processing unit 18 discharges the oxidative aqueous solution L from the lower nozzle 23b toward the rear surface Wb of the peripheral portion Wc of the wafer W being rotated.

As a result, a boron-containing silicon film A (see FIG. 8) formed on the peripheral portion Wc of the wafer W is etched. At this time, a contaminant such as a particle adhering to the peripheral portion Wc of the wafer W is also removed along with the boron-containing silicon film A.

The oxidative aqueous solution L according to the exemplary embodiment is an aqueous solution in which the hydrofluoric acid supplied from the hydrofluoric acid supply 25 and the nitric acid supplied from the nitric acid supply 26 are mixed at a predetermined ratio. Details of the etching processing by this oxidative aqueous solution L will be described later.

Following the discharging of the oxidative aqueous solution L, the periphery processing unit 18 performs a rinsing processing of washing away the oxidative aqueous solution L left on the wafer W by discharging a rinse liquid from the upper and lower nozzles 23a and 23b. Then, the periphery processing unit 18 performs a drying processing of drying the wafer W by rotating the wafer W.

<Configuration of Rear Surface Processing Unit>

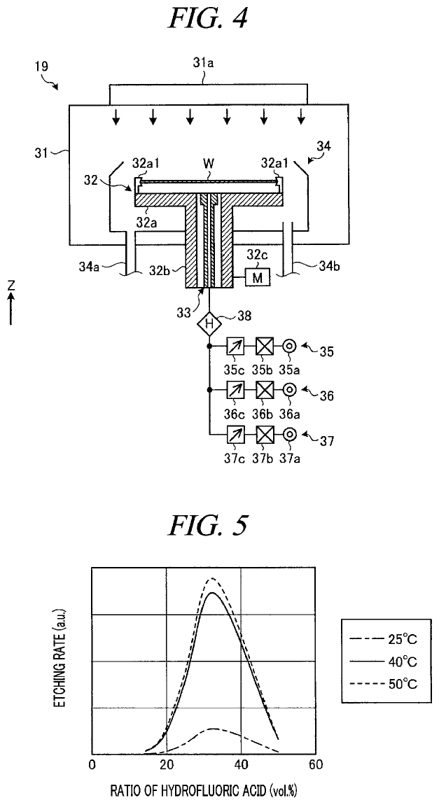

Now, a configuration of the rear surface processing unit 19 according to the exemplary embodiment will be explained with reference to FIG. 4. FIG. 4 is a schematic diagram of the rear surface processing unit 19 according to the exemplar embodiment. As depicted in FIG. 4, the rear surface processing unit 19 includes a chamber 31, a substrate holder 32, a processing liquid supply 33, and a recovery cup 34.

The chamber 31 accommodates therein the substrate holder 32, the processing liquid supply 33 and the recovery cup 34. A FFU 31a configured to form a downflow within the chamber 31 is provided at a ceiling of the chamber 31.

The substrate holder 32 is equipped with a holder 32a configured to hold the wafer W horizontally; a supporting column member 32b vertically extending to support the holder 32a; and a driver 32c configured to rotate the supporting column member 32b around a vertical axis.

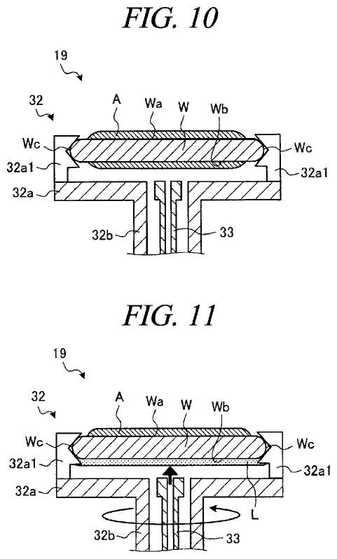

A plurality of grippers 32a1 configured to hold the peripheral portion We (see FIG. 10) of the wafer W is provided on a top surface of the holder 32a, and the wafer W is maintained horizontally while being slightly spaced from the top surface of the holder 32a by these grippers 32a1.

The processing liquid supply 33 is inserted through a hollow portion which is formed through the holder 32a and the supporting column member 32b along a rotation axis. Formed within this processing liquid supply 33 is a path extending along the rotation axis.

A hydrofluoric acid supply 35, a nitric acid supply 36 and a rinse liquid supply 37 are connected to the path formed within the processing liquid supply 33 in parallel. Further, a heater 38 is provided between the processing liquid supply 33; and the hydrofluoric acid supply 35, the nitric acid supply 36 and the rinse liquid supply 37.

The hydrofluoric acid supply 35 has a hydrofluoric acid source 35a, a valve 35b and a flow rate controller 35c in this sequence from an upstream side. The hydrofluoric acid source 35a is, for example, a tank which stores hydrofluoric acid therein. The flow rate controller 35c adjusts a flow rate of the hydrofluoric acid which is supplied to the processing liquid supply 33 from the hydrofluoric acid source 35a via the valve 35b.

The nitric acid supply 36 has a nitric acid source 36a, a valve 36b and a flow rate controller 36c in this sequence from an upstream side. The nitric acid source 36a is, for example, a tank which stores nitric acid therein. The flow rate controller 36c adjusts a flow rate of the nitric acid which is supplied from the nitric acid source 36a to the processing liquid supply 33 via the valve 36b.

The rinse liquid supply 37 has a rinse liquid source 37a, a valve 37b and a flow rate controller 37c in sequence form an upstream side. The rinse liquid source 37a is, for example, a tank which stores a rinse liquid such as, but not limited to, DIW (deionized water) therein. The flow rate controller 37c adjusts a flow rate of the rinse liquid which is supplied from the rinse liquid source 37a to the processing liquid supply 33 via the valve 37b.

The processing liquid supply 33 supplies a chemical liquid supplied from at least one of the hydrofluoric acid supply 35, the nitric acid supply 36 or the rinse liquid supply 37 to the rear surface Wb (see FIG. 10) of the wafer W held by the substrate holder 32.

Further, the rear surface processing unit 19 is capable of heating the chemical liquid discharged from the processing liquid supply 33 to a preset temperature with the heater 38.

The recovery cup 34 is disposed to surround the substrate holder 32. A drain port 24a for draining the chemical liquid supplied from the processing liquid supply 33 to the outside of the chamber 31; and an exhaust port 34b for exhausting an atmosphere within the chamber 31 are formed at a bottom of the recovery cup 34.

The rear surface processing unit 19 having the above-described configuration holds the peripheral portion We of the wafer W with the plurality of grippers 32a1 of the holder 32a, and then rotates the wafer W by using the driver 32c.

Subsequently, the rear surface processing unit 19 discharges the oxidative aqueous solution L (see FIG. 11) from the processing liquid supply 33 toward a central portion of the rear surface Wb of the wafer W being rotated. The oxidative aqueous solution L supplied to the central portion of the rear surface Wb is diffused to the entire rear surface Wb of the wafer W as the wafer W is rotated.

As a result, a boron-containing silicon film A (see FIG. 10) formed on the rear surface Wb of the wafer W is etched. At this time, a contaminant such as a particle adhering to the rear surface Wb of the wafer W is removed along with the boron-containing silicon film A.

Subsequently, the rear surface processing unit 19 performs a rinsing processing of washing away the oxidative aqueous solution L remaining on the wafer W by discharging the rinse liquid from the processing liquid supply 33. Then, the rear surface processing unit 19 performs a drying processing of drying the wafer W by rotating the wafer W.

<Etching Processing of Boron-Containing Silicon Film>

Now, details of the etching processing of the boron-containing silicon film A according to the exemplary embodiment will be described with reference to FIG. 5 to FIG. 10. As stated above, in the exemplary embodiment, the boron-containing silicon film A formed on the wafer W can be appropriately etched with the oxidative aqueous solution L in which the hydrofluoric acid and the nitric acid are mixed at the predetermined ratio. Principles therefor will be described below.

Reactions represented by the following chemical formulas (1) to (3) take place within the nitric acid included in the oxidative aqueous solution L through an autocatalytic cycle.

HNO₂+HNO₃→N₂O₄+H₂O (1)

N₂O₄+2NO₂⇔2NO₂⁻+2h⁺ (2)

2NO₂⁻+2H⁺⇔2HNO₂ (3)

Further, reactions represented by the following chemical formulas (4) to (8) are caused by reaction products produced by the reactions represented by the above-specified chemical formulas (1) to (3). As a result, the silicon included in the boron-containing silicon film A is oxidized.

2NO₂→2NO₂⁻+2h⁺ (4)

2NO₂⁻+2H⁺⇔2HNO₂ (5)

Si⁰+2h⁺→Si²⁺ (6)

Si²⁺+2OH⁻→Si(OH)₂ (7)

Si(OH)₂→SiO₂+H₂O (8)

The silicon oxidized within the boron-containing silicon film A (that is, SiO₂) reacts with the hydrofluoric acid included in the oxidative aqueous solution L, as indicated by the following chemical formula (9), and is dissolved in the oxidative aqueous solution L.

SiO₂+6HF→H₂SiF₆+2H₂O (9)

Like the silicon, the boron included in the boron-containing silicon film A is also oxidized by the oxidative aqueous solution L through a reaction represented by the following chemical formula (10), and dissolved.

B+NO₂+OH⁻→BOₓ+NO₂⁻+H₂O (10)

Moreover, as indicated by the following chemical formula (11), a hydrogen ion (H+) is also produced in the oxidative aqueous solution L due to separation of the nitric acid.

HNO₃⇔NO₃⁻+H⁺ (11)

In addition, the hydrogen ion (H⁺) generated by the reaction represented by the chemical formula (11) is used in the reaction represented by the above-specified chemical formula (5).

As described so far, the silicon and the boron which are the main components of the boron-containing silicon film A formed on the wafer W are both oxidized by an oxidizing power of the nitric acid included in the oxidative aqueous solution L, and these oxides are dissolved by the hydrofluoric acid included in the oxidative aqueous solution L. Accordingly, the boron-containing silicon film A formed on the wafer W can be etched appropriately.

FIG. 5 is a diagram showing a relationship between a ratio of the hydrofluoric acid in the oxidative aqueous solution L and an etching rate of the boron-containing silicon film A. As can be seen from FIG. 5, it is desirable that the mixing ratio between the hydrofluoric acid and the nitric acid in the oxidative aqueous solution L falls within a range from 1:1 (that is, 50 volume % of hydrofluoric acid) to 1:10 (that is, about 9 volume % of hydrofluoric acid).

As stated above, by setting the mixing ratio between the hydrofluoric acid and the nitric acid to be in the range from 1:1 to 1:10, the boron-containing silicon film A formed on the wafer W can be etched at a practically appropriate etching rate.

Furthermore, in the exemplary embodiment, it is more desirable that the mixing ratio between the hydrofluoric acid and the nitric acid in the oxidative aqueous solution L is in a range from 1:5 (that is, about 16 volume % of hydrofluoric acid) to 1:10 (that is, about 9 volume % of hydrofluoric acid).

As stated above, by setting the mixing ratio between the hydrofluoric acid and the nitric acid to be in the range from 1:5 to 1:10, the boron-containing silicon film A formed on the wafer W can be etched at a practically appropriate etching rate, and, also, generation of NOx from the oxidative aqueous solution L can be suppressed.

Additionally, in the present exemplary embodiment, the mixing ratio between the hydrofluoric acid and the nitric acid in the oxidative aqueous solution L may be in a range from 1:1.5 (that is, about 40 volume % of hydrofluoric acid) to 1:3 (that is, about 25 volume % of hydrofluoric acid).

As described above, by setting the mixing ratio between the hydrofluoric acid and the nitric acid to be in the range from 1:1.5 to 1:3, the etching rate of the boron-containing silicon film A can be improved.

Moreover, in the present exemplary embodiment, it is desirable that a temperature of the oxidative aqueous solution L is in a range from 20° C. to 80° C. when the boron-containing silicon film A is etched. By setting the temperature of the oxidative aqueous solution L to be in this range, the boron-containing silicon film A can be etched at a practically appropriate etching rate.

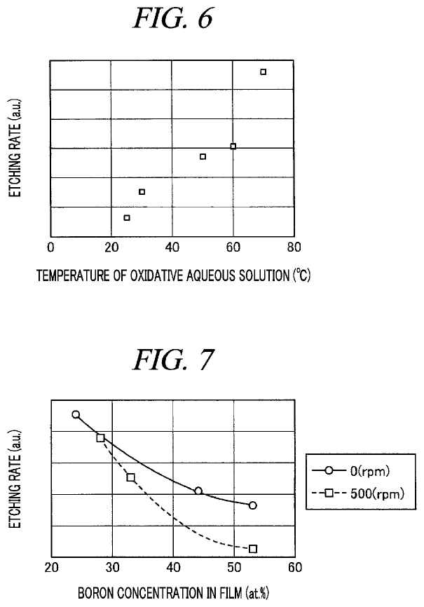

In addition, in the exemplary embodiment, it is more desirable that the temperature of the oxidative aqueous solution Lis in a range from 30° C. to 60° C. By setting the temperature of the oxidative aqueous solution L to be equal to or higher than 30° C., the etching rate of the boron-containing silicon film A can be improved greatly as compared to a case where the etching is performed at a room temperature (25° C.), as shown in FIG. 6.

Further, by setting the temperature of the oxidative aqueous solution L to be equal to or lower than 60° C., the individual components of the substrate processing system 1 (see FIG. 1) can be suppressed from being degraded by the high-temperature oxidative aqueous solution L. FIG. 6 is a diagram showing a relationship between the temperature of the oxidative aqueous solution L and the etching rate of the boron-containing silicon film A.

FIG. 6 presents an experiment result obtained when a boron concentration in the boron-containing silicon film A is 33 atom % and the mixing ratio between the hydrofluoric acid and the nitric acid in the oxidative aqueous solution L is 1:6.

FIG. 7 is a diagram showing a relationship between the boron concentration in the boron-containing silicon film A and the etching rate of the boron-containing silicon film A. As can be seen from FIG. 7, in the present exemplary embodiment, the etching rate of the boron-containing silicon film A is found to be improved when a rotation number of the wafer W is small.

The reason for this is deemed to be as follows. In the exemplary embodiment, the boron (B) and the silicon (Si) are dissolved by using an oxidizing power of an intermediate (for example, NO₂) included in the oxidative aqueous solution L, as indicated by the above-specified chemical formulas (1) to (11).

If the rotation number of the wafer W is set to be excessively large, this intermediate is reduced in the oxidative aqueous solution L which is in contact with the wafer W. Thus, if the rotation number of the wafer W is set to be excessively large, the etching rate of the boron-containing silicon film A is reduced.

Meanwhile, if the rotation number of the wafer W is set to be small, a concentration of the intermediate in the oxidative aqueous solution L in contact with the wafer W can be maintained. Thus, by setting the rotation number of the wafer W to be small within a practically available range, the etching rate of the boron-containing silicon film A can be improved.

By way of example, when etching the rear surface Wb of the wafer W with the oxidative aqueous solution L, it is desirable to set the rotation number of the wafer W to be in a range from 200 rpm to 1000 rpm. Further, when etching the peripheral portion We of the wafer W with the oxidative aqueous solution L, it is desirable to set the rotation number of the wafer W to be in a range from 400 rpm to 1000 rpm.

According to the exemplary embodiment, by setting the rotation number to be in these ranges, the etching rate of the boron-containing silicon film A can be bettered.

Desirably, the oxidative aqueous solution L according to the exemplary embodiment is composed of the hydrofluoric acid, the nitric acid, and the inevitable impurity. Further, in the present exemplary embodiment, this oxidative aqueous solution L may further include acetic acid.

By adopting these compositions, excessive etching by the oxidative aqueous solution L can be suppressed, so that a surface of the boron-containing silicon film A can be suppressed from being etched roughly.

Additionally, in the present exemplary embodiment, it is desirable that the boron-containing silicon film A contains the boron within a range from 20 atom % to 80 atom %. By setting the boron concentration to be in this range, this boron-containing silicon film A can be appropriately used as a hard mask when etching the wafer W.

Now, individual processes of the etching processing according to the exemplary embodiment will be elaborated. FIG. 8 is a diagram for describing a holding processing of the wafer W in the periphery processing unit 18 according to the exemplary embodiment.

First, the wafer W is transferred into the periphery processing unit 18 by using the transfer section 12 (see FIG. 1) and the transfer section 16 (see FIG. 1). Then, the controller 6 (see FIG. 1) performs a processing of holding the wafer W with the holder 22a by operating the substrate holder 22.

Further, prior to this processing of holding the wafer W, the boron-containing silicon film A is formed on the entire surface of the wafer W (that is, the front surface Wa, the rear surface Wb and the peripheral portion Wc of the wafer W), as illustrated in FIG. 8. In the exemplary embodiment, the rear surface Wb on which the boron-containing silicon film A is formed is attracted to and held by the holder 22a.

Further, in the present disclosure, the front surface Wa of the wafer W refers to a main surface on which a pattern (a circuit formed to have a protruding shape) is formed, and the rear surface Wb refers to a main surface opposite from the front surface Wa.

Following the holding processing, a supplying processing of supplying the oxidative aqueous solution L to the peripheral portion Wc of the wafer W is performed in the exemplary embodiment. FIG. 9 is a diagram for describing the supplying processing of supplying the oxidative aqueous solution L to the peripheral portion Wc of the wafer W according to the exemplary embodiment.

First, the controller 6 (see FIG. 1) operates the driver 22c (see FIG. 3) to thereby rotate the wafer W at a preset rotation number (e.g., 400 rpm to 1000 rpm), as shown in FIG. 9.

Then, the controller 6 operates the upper nozzle 23a to thereby supply the oxidative aqueous solution L toward the front surface Wa of the peripheral portion Wc of the wafer W being rotated. Further, the controller 6 also operates the lower nozzle 23b to thereby supply the oxidative aqueous solution L toward the rear surface Wb of the peripheral portion Wc of the wafer W being rotated.

Accordingly, as illustrated in FIG. 9, the boron-containing silicon film A formed at the peripheral portion Wc of the wafer W can be appropriately etched.

Thereafter, by rotating the wafer W at a high speed (e.g., 1500 rpm) and operating the upper and lower nozzles 23a and 23b, the controller 6 performs a rinsing processing of supplying the rinse liquid to the peripheral portion Wc of the wafer W to thereby wash away the oxidative aqueous solution L left thereat.

Next, the controller 6 performs a drying processing of drying the wafer W by stopping the supply of the rinse liquid while carrying on the high-speed rotation of the wafer W.

Following this drying processing, a processing of transferring the wafer W into the rear surface processing unit 19 and holding the wafer W thereat is performed in the exemplary embodiment. FIG. 10 is a diagram for describing this holding processing of holding the wafer W in the rear surface processing unit 19 according to the exemplary embodiment.

First, the wafer W is transferred from the periphery processing unit 18 into the rear surface processing unit 19 by using the transfer section 16 (see FIG. 1) and so forth. Then, the controller 6 (see FIG. 1) performs the holding processing of holding the wafer W with the holder 32a by operating the substrate holder 32.

Further, in the exemplary embodiment, the peripheral portion We of the wafer W from which the boron-containing silicon film A is etched is held by the plurality of grippers 32a1, as shown in FIG. 10.

Following this holding processing, a supplying processing of supplying the oxidative aqueous solution L to the rear surface Wb of the wafer W is performed in the exemplary embodiment. FIG. 11 is a diagram for describing the supplying processing of supplying the oxidative aqueous solution L to the rear surface Wb of the wafer W according to the exemplary embodiment.

First, the controller 6 (see FIG. 1) operates the driver 32c (see FIG. 4) to thereby rotate the wafer W at a preset rotation number (e.g., 200 rpm to 1000 rpm), as shown in FIG. 11.

Then, the controller 6 operates the processing liquid supply 33 to thereby supply the oxidative aqueous solution L toward a central portion of the rear surface Wb the wafer W being rotated. The oxidative aqueous solution L supplied to the central portion of the rear surface Wb is diffused to the entire rear surface Wb of the wafer W as the wafer W is rotated.

Accordingly, as illustrated in FIG. 11, the boron-containing silicon film A formed on the rear surface Wb of the wafer W can be appropriately etched.

Thereafter, by rotating the wafer W at a high speed (e.g., 1500 rpm) and operating the processing liquid supply 33, the controller 6 performs a rinsing processing of supplying the rinse liquid to the rear surface Wb of the wafer W to thereby wash away the oxidative aqueous solution L left thereon.

Next, the controller 6 performs a drying processing of drying the wafer W by stopping the supply of the rinse liquid while carrying on the high-speed rotation of the wafer W. Through the series of processings described so far, the processing of etching the boron-containing silicon film A formed on the rear surface Wb and the peripheral portion Wc of the wafer W is completed.

Further, though the above exemplary embodiment has been described for the example where the rear surface Wb of the wafer W is etched after the peripheral portion Wc of the wafer W is etched, it may be possible to etch the peripheral portion Wc of the wafer W after etching the rear surface Wb of the wafer W.

Meanwhile, in the exemplary embodiment, by etching the rear surface Wb of the wafer W after etching the peripheral portion Wc of the wafer W, a trace of the wafer W attracted to and held by the holder 22a can be suppressed from being left on the rear surface Wb of the wafer W.

### MODIFICATION EXAMPLES

In the exemplary embodiment described so far, the etching processing is performed by discharging the oxidative aqueous solution L to the rear surface Wb or the peripheral portion We of the wafer W. However, the etching processing according to the exemplary embodiment is not limited thereto.

For example, by discharging the oxidative aqueous solution L onto the front surface Wa of the wafer W being rotated, the boron-containing silicon film A formed on the front surface Wa of the wafer W can be etched with the oxidative aqueous solution L. Accordingly, the boron-containing silicon film A formed on the front surface Wa of the wafer W can be etched appropriately.

Further, in the exemplary embodiment, when etching the front surface Wa of the wafer W with the oxidative aqueous solution L, it is desirable to set the rotation number of the wafer W to be in a range from 10 rpm to 1000 rpm. By setting the rotation number to be in this range, the concentration of the intermediate in the oxidative aqueous solution L in contact with the wafer W can be maintained so that the etching rate of the boron-containing silicon film A can be improved.

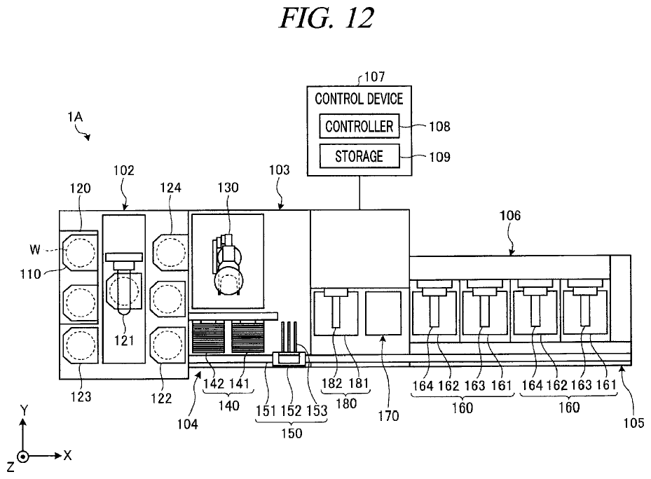

Moreover, though the above exemplary embodiment has been described for the example where the wafer W is etched by a single-wafer processing, the etching processing according to the exemplary embodiment is not limited to the single-wafer processing. FIG. 12 is a schematic plan view of a substrate processing system 1A according to a modification example of the exemplary embodiment.

The substrate processing system 1A according to a modification example 1 shown in FIG. 12 is another example of the substrate processing apparatus, and is capable of processing a multiple number of wafers W all at once. The substrate processing system 1A according to the modification example includes a carrier carry-in/out unit 102, a lot forming unit 103, a lot placing unit 104, a lot transferring unit 105, a lot processing unit 106, and a controller 107.

The carrier carry-in/out unit 102 is equipped with a carrier stage 120, a carrier transfer device 121, carrier stocks 122 and 123, and a carrier placing table 124.

The carrier stage 120 places thereon a plurality of carriers 110 transferred from the outside. Each of the carriers 110 is a container configured to accommodate a plurality (e.g., twenty five sheets) of wafers W while allowing the wafers to be vertically arranged in a horizontal posture. The carrier transfer device 121 transfers the carriers 110 between the carrier stage 120, the carrier stocks 122 and 123 and the carrier placing table 124.

A plurality of wafers W before being processed is carried out from the carrier 110 placed on the carrier placing table 124 into the lot processing unit 106 by a substrate transfer mechanism 130 to be described later. Further, a plurality of wafers W after being processed is carried into the carrier 110 placed on the carrier placing table 124 from the lot processing unit 106 by the substrate transfer device 130.

The lot forming unit 103 is equipped with the substrate transfer device 130 to form a lot. The lot is formed of a plurality (e.g., fifty sheets) of wafers W to be processed simultaneously by combining wafers W accommodated in one or more carriers 110. For example, the wafers W in the lot are arranged with their plate surfaces facing each other at a predetermined interval.

The substrate transfer device 130 transfers the wafers W between the carrier 110 placed on the carrier placing table 124 and the lot placing unit 104.

The lot placing unit 104 is equipped with a lot placing table 140 to temporarily place (stand by) a lot to be transferred between the lot forming unit 103 and the lot processing unit 106 by the lot transferring unit 105.

The lot placing table 140 is equipped with a lot placing table 141 on which a lot before being processed, which is formed by the lot forming unit 103, is placed; and a lot placing table 142 on which a lot after being processed by the lot processing unit 106 is placed. On the lot placing tables 141 and 142, the wafers W belonging to a single lot are arranged side by side in an upright posture.

The lot transferring unit 105 is equipped with a lot transferring device 150, and configured to transfer the lot between the lot placing unit 104 and the lot processing unit 106 or within the lot processing unit 106. The lot transferring device 150 is equipped with a rail 151, a moving body 152, and a substrate holding body 153.

The rail 151 is placed along the lot placing unit 104 and the lot processing unit 106 in the X-axis direction. The moving body 152 is configured to be movable along the rail 151 while holding the wafers W. The substrate holding body 153 is provided on the moving body 152 to hold the wafers W arranged side by side in the upright posture.

The lot processing unit 106 performs an etching processing, a cleaning processing and a drying processing to the wafers W belonging to the single lot. In the lot processing unit 106, two entire surface processing units 160, a cleaning apparatus 170, and a drying apparatus 180 are provided along the rail 151.

The entire surface processing unit 160 performs the etching processing and the rinsing processing on the plurality of wafers W belonging to the single lot all at once. The cleaning apparatus 170 performs a cleaning processing of the substrate holding body 153. The drying apparatus 180 performs a drying processing on the plurality of wafers W belonging to the single lot all at once. Further, the number of the entire surface processing units 160, the number of the cleaning apparatus 170, and the number of the drying apparatus 180 are not limited to the example shown in FIG. 12.

The entire surface processing unit 160 is equipped with a processing tub 161 for etching, a processing tub 162 for rinsing, and substrate holders 163 and 164 configured to be movable up and down. Each of the processing tubs 161 and 162 is capable of accommodating therein the plurality of wafers W of the single lot. Further, the oxidative aqueous solution L as an etching liquid is stored in the processing tub 161. Details of the processing tub 161 of the entire surface processing unit 160 will be elaborated later.

The processing tub 162 stores therein a rinse liquid for rinsing. Each of the substrate holders 163 and 164 holds the plurality of wafers W of the single lot thereon while allowing the wafers W to be arranged side by side in the upright position.

The entire surface processing unit 160 holds, with the substrate holder 163, the lot transferred by the lot transferring unit 105, and performs the etching processing by immersing the lot in the oxidative aqueous solution L of the processing tub 161. Further, the entire surface processing unit 160 holds the lot transferred into the processing tub 162 by the lot transferring unit 105 with the substrate holder 164, and performs the rinsing processing by immersing the lot in the rinse liquid of the processing tub 162.

The drying apparatus 180 is equipped with a processing tub 181 and a substrate holder 182 configured to be movable up and down. A processing gas for drying is supplied into the processing tub 181. The substrate holder 182 holds the plurality of wafers W of the single lot thereon while allowing the wafers to be arranged side by side in the upright posture.

The drying apparatus 180 holds, with the substrate holder 182, the lot transferred by the lot transferring unit 105, and performs the drying processing by using the processing gas for drying supplied into the processing tub 181. The lot after being subjected to the drying processing in the processing tub 181 is transferred into the lot placing unit 104 by the lot transferring unit 105.

The cleaning apparatus 170 performs a cleaning processing upon the substrate holding body 153 of the lot transferring device 150 by supplying a processing liquid for cleaning and, also, a drying gas to the substrate holding body 153.

The control device 107 is implemented by, for example, a computer, and includes a controller 108 and a storage 109. The storage 109 stores a program for controlling various processing performed in the substrate processing system 1A. The controller 108 operates an operation of the substrate processing system 1A by reading and executing the program stored in the storage 109.

Further, this program may be recorded on a computer-readable recording medium and installed from this recording medium to the storage 109 of the control device 107.

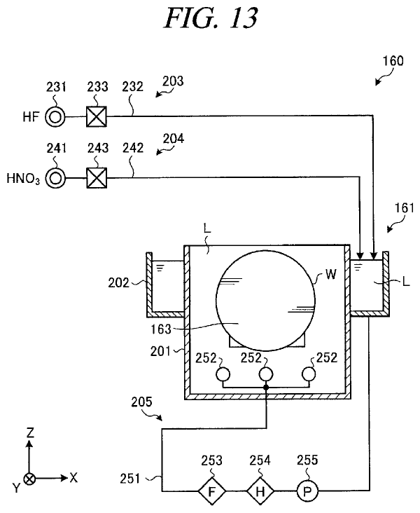

FIG. 13 is a schematic diagram illustrating the processing tub 161 of the entire surface processing unit 160 according to the modification example of the exemplary embodiment.

As depicted in FIG. 13, the processing tub 161 for etching includes an inner tub 201 and an outer tub 202. The inner tub 201 is a box-shaped water tub having an open top, and stores therein the oxidative aqueous solution L.

The lot composed of the plurality of wafers W is immersed in the inner tub 201. The outer tub 202 has an open top and disposed around an upper portion of the inner tub 201. The oxidative aqueous solution L overflown from the inner tub 201 is flown into the outer tub 202.

Further, the processing tub 161 is equipped with a hydrofluoric acid supply 203 and a nitric acid supply 204. The hydrofluoric acid supply 203 includes a hydrofluoric acid source 231, a hydrofluoric acid supply line 232 and a flow rate controller 233.

The hydrofluoric acid source 231 is, for example, a tank which stores hydrofluoric acid therein. The hydrofluoric acid supply line 232 connects the hydrofluoric acid source 231 and the outer tub 202, and supplies the hydrofluoric acid from the hydrofluoric acid source 231 into the outer tub 202.

The flow rate controller 233 is provided at the hydrofluoric acid supply line 232 and serves to adjust a supply amount of the hydrofluoric acid to be supplied into the outer tub 202. The flow rate controller 233 is composed of an opening/closing valve, a flow rate control valve, a flowmeter, and so forth. As the supply amount of the hydrofluoric acid is adjusted by the flow rate controller 233, a hydrofluoric acid concentration of the oxidative aqueous solution L is adjusted.

The nitric acid supply 204 is equipped with a nitric acid source 241, a nitric acid supply line 242 and a flow rate controller 243. The nitric acid source 241 is, for example, a tank which store nitric acid therein. The nitric acid supply line 242 connects the nitric acid source 241 and the outer tub 202, and supplies the nitric acid from the nitric acid source 241 into the outer tub 202.

The flow rate controller 243 is provided at the nitric acid supply line 242 and serves to adjust a supply amount of the nitric acid to be supplied into the outer tub 202. The flow rate controller 243 is composed of an opening/closing valve, a flow rate control valve, a flowmeter, and so forth. As the supply amount of the nitric acid is adjusted by the flow rate controller 243, a nitric acid concentration of the oxidative aqueous solution L is adjusted.

Further, the processing tub 161 is equipped with a processing liquid supply 205 configured to supply the oxidative aqueous solution L to the plurality wafers W held by the substrate holder 163 within the inner tub 201. This processing liquid supply 205 circulates the oxidative aqueous solution L between the inner tub 201 and the outer tub 202.

The processing liquid supply 205 is equipped with a circulation line 251, a plurality of supply nozzles 252, a filter 253, a heater 254, and a pump 255.

The circulation line 251 connects the outer tub 202 and the inner tub 201. One end of the circulation line 251 is connected to the outer tub 202, and the other end of the circulation line 251 is connected to the plurality of supply nozzles 252 disposed within the inner tub 201.

The circulation line 251 is provided with the filter 253, the heater 254 and the pump 255. The filter 253 removes an impurity from the oxidative aqueous solution L flowing in the circulation line 251. The heater 254 heats the oxidative aqueous solution L flowing in the circulation line 251 to a predetermined temperature. The pump 255 sends the oxidative aqueous solution L within the outer tub 202 into the circulation line 251. The pump 255, the heater 254 and the filter 253 are arranged in this sequence from an upstream side.

The processing liquid supply 205 sends the oxidative aqueous solution L from the outer tub 202 into the inner tub 201 via the circulation line 251 and the plurality of supply nozzles 252. The oxidative aqueous solution L sent into the inner tub 201 overflows from the inner tub 201 and flows back into the outer tub 202. Accordingly, the oxidative aqueous solution L is circulated between the inner tub 201 and the outer tub 202.

In the substrate processing system 1A described so far, by supplying the oxidative aqueous solution L to the entire surface of the wafer W within the entire surface processing unit 160, the boron-containing silicon film A formed on the entire surface of the wafer W can be appropriately etched.

By way of example, in the modification example, when reworking the wafer W having the boron-containing silicon film A formed on the entire surface thereof, this wafer W can be reworked efficiently.

Further, in the modification example, the plurality of wafers W can be processed all at once with the oxidative aqueous solution L in the entire surface processing unit 160. Thus, according to the modification example, the plurality of wafers W each of which has the boron-containing silicon film A formed on the entire surface thereof can be etched with a high throughput.

The substrate processing apparatus (substrate processing systems 1 and 1A) according to the exemplary embodiment includes the substrate holder 22 (32, 163) and the processing liquid supply 23 (33, 205). The substrate holder 22 (32) holds the substrate (wafer W) on which the boron-containing silicon film A is formed. The processing liquid supply 23 (33, 205) supplies the oxidative aqueous solution L including the hydrofluoric acid and the nitric acid to the substrate (wafer W) held by the substrate holder 22 (32, 163). Accordingly, the boron-containing silicon film A formed on the wafer W can be etched appropriately.

Further, in the substrate processing apparatus (substrate processing system 1) according to the exemplary embodiment, the processing liquid supply 33 supplies the oxidative aqueous solution L to the rear surface Wb of the substrate (wafer W). Accordingly, the boron-containing silicon film A formed on the rear surface Wb of the wafer W can be etched appropriately.

Moreover, in the substrate processing apparatus (substrate processing system 1) according to the exemplary embodiment, the substrate holder 32 holds the substrate (wafer W) rotatably. Further, the processing liquid supply 33 supplies the oxidative aqueous solution L to the rear surface Wb of the substrate (wafer W) being rotated at the rotation number ranging from 200 rpm to 1000 rpm. Accordingly, the etching rate of the boron-containing silicon film A formed on the rear surface Wb of the wafer W can be improved.

In addition, in the substrate processing apparatus (substrate processing system 1) according to the exemplary embodiment, the processing liquid supply 23 supplies the oxidative aqueous solution L to the peripheral portion Wc of the substrate (wafer W). Accordingly, the boron-containing silicon film A formed at the peripheral portion Wc of the wafer W can be etched appropriately.

Further, in the substrate processing apparatus (substrate processing system 1) according to the exemplary embodiment, the substrate holder 22 holds the substrate (wafer W) rotatably. Furthermore, the processing liquid supply 23 supplies the oxidative aqueous solution L to the peripheral portion Wc of the substrate (wafer W) being rotated at the rotation number ranging from 400 rpm to 1000 rpm. Accordingly, the etching rate of the boron-containing silicon film A formed at the peripheral portion Wc of the wafer W can be improved.

<Processing Sequence>

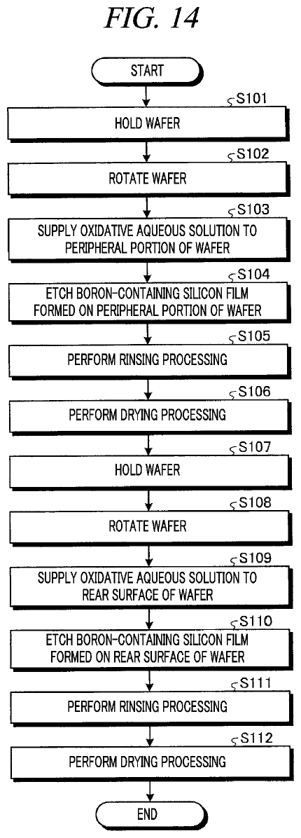

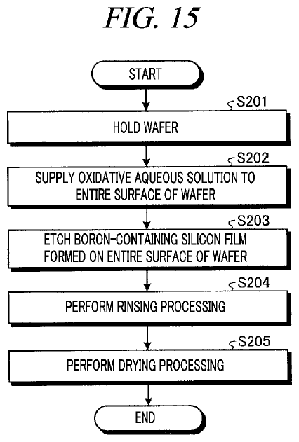

Now, a sequence of a substrate processing according to the exemplary embodiment will be explained with referenced to FIG. 14 and FIG. 15. FIG. 14 is a flowchart illustrating a sequence of a substrate processing performed by the substrate processing system 1 according to the exemplary embodiment.

First, the controller 6 transfers the wafer W into the periphery processing unit 18 by using the transfer section 12, the transfer section 16, and the like. Then, the controller 6 controls the periphery processing unit 18 to hold the wafer W with the substrate holder 22 (process S101).

Subsequently, the controller 6 controls the periphery processing unit 18 to rotate the wafer W held by the substrate holder 22 at a preset rotation number (for example, 400 rpm to 1000 rpm) (process S102).

Thereafter, the controller 6 controls the periphery processing unit 18 to supply the oxidative aqueous solution L to the peripheral portion Wc of the wafer W being rotated (process S103). Then, the controller 6 etches the boron-containing silicon film A formed at the peripheral portion Wc of the wafer W by this oxidative aqueous solution L (process S104).

Next, the controller 6 performs a rinsing processing on the wafer W by supplying the rinse liquid to the peripheral portion We of the wafer W being rotated at the high speed (process S105). Then, by stopping the supply of the rinse liquid, the controller 6 performs a drying processing on the wafer W (process S106).

Afterwards, the controller 6 transfers the wafer W into the rear surface processing unit 19 from the periphery processing unit 18 by using the transfer section 16 or the like. Then, the controller 6 controls the rear surface processing unit 19 to hold the wafer W with the substrate holder 32 (process S107).

Then, the controller 6 controls the rear surface processing unit 19 to rotate the wafer W held by the substrate holder 32 at a predetermined rotation number (for example, 200 rpm to 1000 rpm) (process S108).

Subsequently, the controller 6 controls the rear surface processing unit 19 to supply the oxidative aqueous solution L to the rear surface Wb of the wafer W being rotated (process S109). Then, the controller 6 etches the boron-containing silicon film A formed on the rear surface Wb of the wafer W by this oxidative aqueous solution L (process S110).

Thereafter, the controller 6 performs a rinsing processing on the wafer W by supplying the rinse liquid to the rear surface Wb of the wafer W being rotated at the high speed (process S111). Then, by stopping the supply of the rinse liquid, the controller 6 performs a drying processing on the wafer W (process S112), and ends the substrate processing.

FIG. 15 is a flowchart illustrating a sequence of a substrate processing performed by the substrate processing system 1A according to the modification example of the exemplary embodiment.

First, the controller 108 transfers a plurality of wafers W of a single lot into the lot processing unit 106 by controlling the carrier carry-in/out unit 102, the lot forming unit 103, the lot placing unit 104, the lot transferring unit 105, and so forth. Then, the controller 6 controls the lot transferring unit 105 and the lot processing unit 106 to hold the plurality of wafers W of the single lot with the substrate holder 163 of the entire surface processing unit 160 (process S201).

Then, the controller 108 controls the processing liquid supply 205 to supply the oxidative aqueous solution L into the inner tub 201, and by lowering the substrate holder 163 into the inner tub 201, the controller 108 allows the oxidative aqueous solution L to be supplied to the entire surfaces of the plurality of wafers W of the single lot (process S202). Then, the controller 108 etches a boron-containing silicon film A formed on the entire surface of the each of the plurality of wafers W by this oxidative aqueous solution L (process S203).

Thereafter, the controller 108 controls the lot transferring unit 105 or the like to transfer the plurality of wafers W of the single lot to the substrate holder 164 from the substrate holder 163 of the entire surface processing unit 160. Then, the controller 108 lowers the substrate holder 164 into the processing tub 162 for rinsing, thus allowing the entire surfaces of the plurality of wafers W of the single lot to be rinsed (process S204).

Subsequently, the controller 108 controls the lot transferring unit 105 or the like to transfer the plurality of wafers W of the single lot into the drying apparatus 180 from the substrate holder 164 of the entire surface processing unit 160. In the drying apparatus 180, the controller 108 performs a drying processing on the entire surfaces of the plurality of wafers W of the single lot (process S205), and ends the substrate processing.

A substrate processing method according to the exemplary embodiments includes the holding process (processes S101, S107 and S201), the supplying process (processes S103, S109 and S202), and the etching process (processes S104, S110 and S203). In the holding process (processes S101, S107 and S201), the substrate (wafer W) on which the boron-containing silicon film A is formed is held. In the supplying process (processes S103, S109 and S202), the oxidative aqueous solution L including the hydrofluoric acid and the nitric acid is supplied to the held substrate (wafer W). In the etching process (processes S104, S110 and S203), the boron-containing silicon film A of the substrate (wafer W) is etched by the oxidative aqueous solution L. Accordingly, the boron-containing silicon film A formed on the wafer W can be etched appropriately.

Further, in the substrate processing method according to the exemplary embodiment, the mixing ratio between the hydrofluoric acid and the nitric acid in the oxidative aqueous solution L is in the range from 1:1 to 1:10. Accordingly, the boron-containing silicon film A formed on the wafer W can be etched at a practically appropriate etching rate.

Furthermore, in the substrate processing method according to the exemplary embodiment, the temperature of the oxidative aqueous solution L is in the range from 20° C. to 80° C. Accordingly, the boron-containing silicon film A can be etched at a practically appropriate etching rate.

In addition, in the substrate processing method according to the exemplary embodiment, the oxidative aqueous solution L further includes acetic acid. Accordingly, the surface of the boron-containing silicon film A can be suppressed from being roughly etched.

Moreover, in the substrate processing method according to the exemplary embodiment, the oxidative aqueous solution L is supplied to the peripheral portion Wc of the substrate (wafer W) in the supplying process (process S103). Accordingly, the boron-containing silicon film A formed at the peripheral portion Wc of the wafer W can be etched appropriately.

Additionally, in the substrate processing method according to the exemplary embodiment, the oxidative aqueous solution L is supplied to the rear surface Wb of the substrate (wafer W) in the supplying process (process S109). Accordingly, the boron-containing silicon film A formed on the rear surface Wb of the wafer W can be etched appropriately.

Furthermore, in the substrate processing method according to the exemplary embodiment, the oxidative aqueous solution L is supplied to the entire surface of the substrate (wafer W) in the supplying process (process S202). Accordingly, the boron-containing silicon film A formed on the entire surface of the wafer W can be etched appropriately.

So far, the exemplary embodiments of the preset disclosure have been described. However, the present disclosure is not limited to the above-described exemplary embodiments, and various changes and modifications may be made without departing from the sprint and scope of the present disclosure. By way of example, though the above exemplary embodiments have been described for the example where the oxidative aqueous solution L produced by mixing the hydrofluoric acid stored in the hydrofluoric acid source and the nitric acid stored in the nitric acid source within the pipeline at the predetermined mixing ratio is supplied into the individual units, the way how to supply the oxidative aqueous solution L is not limited to this example.

By way of example, a fluonitric acid source which stores therein fluonitric acid (that is, oxidative aqueous solution L) produced by mixing hydrofluoric acid and nitric acid at a preset mixing ratio is prepared, and the oxidative aqueous solution L stored in this fluonitric acid source can be supplied into the individual units. Accordingly, a pipeline configuration of the individual units (the periphery processing unit 18, the rear surface processing unit 19 and the entire surface processing unit 160) can be simplified.

It should be noted that the above-described exemplary embodiments are illustrative in all aspects and are not anyway limiting. In fact, the above-described exemplary embodiments can be embodied in various forms. The above-described exemplary embodiments may be omitted, replaced and modified in various ways without departing from the scope and the spirit of claims.

According to the exemplary embodiment, the boron-containing silicon film formed on the wafer can be appropriately etched.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing method, comprising:
holding a substrate on which a boron-containing silicon film is formed;
supplying an oxidative aqueous solution including hydrofluoric acid and nitric acid to the held substrate; and
etching the boron-containing silicon film of the substrate with the oxidative aqueous solution.

2. The substrate processing method of claim 1,
wherein a mixing ratio between the hydrofluoric acid and the nitric acid in the oxidative aqueous solution is in a range from 1:1 to 1:10.

3. The substrate processing method of claim 2,
wherein a temperature of the oxidative aqueous solution is in a range from 20° C. to 80° C.

4. The substrate processing method of claim 2,
wherein the oxidative aqueous solution further includes acetic acid.

5. The substrate processing method of claim 2,
wherein in the supplying of the oxidative aqueous solution, the oxidative aqueous solution is supplied to a peripheral portion of the substrate.

6. The substrate processing method of claim 2,
wherein in the supplying of the oxidative aqueous solution, the oxidative aqueous solution is supplied to a rear surface of the substrate.

7. The substrate processing method of claim 2,
wherein in the supplying of the oxidative aqueous solution, the oxidative aqueous solution is supplied to an entire surface of the substrate.

8. The substrate processing method of claim 1,
wherein a temperature of the oxidative aqueous solution is in a range from 20° C. to 80° C.

9. The substrate processing method of claim 1,
wherein the oxidative aqueous solution further includes acetic acid.

10. The substrate processing method of claim 1,
wherein in the supplying of the oxidative aqueous solution, the oxidative aqueous solution is supplied to a peripheral portion of the substrate.

11. The substrate processing method of claim 1,
wherein in the supplying of the oxidative aqueous solution, the oxidative aqueous solution is supplied to a rear surface of the substrate.

12. The substrate processing method of claim 1,
wherein in the supplying of the oxidative aqueous solution, the oxidative aqueous solution is supplied to an entire surface of the substrate.

13. A substrate processing apparatus, comprising:
a substrate holder configured to hold a substrate on which a boron-containing silicon film is formed; and
a processing liquid supply configured to supply an oxidative aqueous solution including hydrofluoric acid and nitric acid to the substrate held by the substrate holder.

14. The substrate processing apparatus of claim 13,
wherein the processing liquid supply supplies the oxidative aqueous solution to a rear surface of the substrate.

15. The substrate processing apparatus of claim 14,
wherein the substrate holder holds the substrate rotatably, and
the processing liquid supply supplies the oxidative aqueous solution to the rear surface of the substrate being rotated at a rotation number ranging from 200 rpm to 1000 rpm.

16. The substrate processing apparatus of claim 13,
wherein the processing liquid supply supplies the oxidative aqueous solution to a peripheral portion of the substrate.

17. The substrate processing apparatus of claim 16,
wherein the substrate holder holds the substrate rotatably, and
the processing liquid supply supplies the oxidative aqueous solution to the peripheral portion of the substrate being rotated at a rotation number ranging from 400 rpm to 1000 rpm.
